(19) United States
(12) Patent Application Publication
(10) Pub. No.: US 2004/0175907 A1
(43) Pub. Date: Sep. 9, 2004

(54) Method of fabricating a salicided device using a dummy dielectric layer between the source/drain and the gate electrode

(75) Inventors: Horng-Huei Tseng, Hsin-Chu (TW); Da-Chi Lin, Hsin-Chu (TW); Kuo-Nan Yang, Taipei (TW); Chenming Hu, Hsinchu (TW)

Correspondence Address: STEPHEN B. ACKERMAN, 20 MCINTOSH DRIVE, POUGHKEEPSIE, NY, 12603, US

(73) Assignee: Taiwan Semiconductor Manfacturing Company

(21) Appl. No.: 10/383,711

(22) Filed: Mar. 7, 2003

(51) Int. Cl. H01L 21/4763

(52) U.S. Cl. 438/589

(57) ABSTRACT

A new method is provided for the creation of CMOS devices. A sacrificial layer is deposited over a silicon substrate. This sacrificial layer is instrumental in creating gate spacers and in doing so serves to separate the gate from the source/drain regions in a self-aligned manner.

### BACKGROUND OF THE INVENTION

(1) Field of the Invention

The invention relates to the fabrication of integrated circuit devices, and more particularly, to a method of forming a self-aligned salicided MOSFET devices having ultra-shallow source and drain regions.

(2) Description of the Prior Art

Continued improvement in semiconductor performance has resulted in the extension of the art for the creation of Very Large Scale Integrated (VLSI) devices to the field of Ultra Large Scale Integrated (ULSI) devices. For ULSI devices, device feature size is at this time in the micron and sub-micron range, continued development work is taking place relating to deep sub-micron sizes that reach below 0.5 μm. These further developments are supported by advances in semiconductor technologies such as photolithography and improved etching techniques such as Reactive Ion Etching (RIE).

The technique of creating complementary n-channel and p channel MOSFET devices is well known. A major advantage of these devices is their low power usage due to the fact that two transistors can be paired as complementary n-channel and p-channel transistors. In either logic on/off state of the device, one of the two transistors is off and negligible current is carried through this transistor. Therefore, the logic elements of Complementary Metal Oxide Semiconductor (CMOS) devices drain significant amounts of current only at the time that these devices switch from one state to another state. Between these transitions the devices draw very little current resulting in low power dissipation for the CMOS device.

The invention addresses the concern that, for gate electrode structures that are created for the ULSI era, having ultra-shallow source and drain implantations, the process of source and drain surface salicidation cannot be used due to the ultra-shallow junction depth of the source/drain region implantations. By not saliciding the source/drain regions, a high series resistance to these regions is introduced, degrading the device performance. On the other hand, an alternate approach to creating low-resistance contact with the source/drain regions by the process of selective epitaxy growth for the purpose of creating elevated source/drain surfaces as yet encounters problems for gate electrodes having sub-micron device features. The invention addresses these problems and provides solutions thereto.

U.S. Pat. No. 6,358,800 B1 (Tseng) provides a method of forming a MOSFET device with a recessed gate having a channel length beyond photolithographic limits.

U.S. Pat. No. 5,434,093 (Chau et al.) provides for the creation of an inverted spacer transistor.

U.S. Pat. No. 6,100,146 (Gardner et al.) provides a method for forming a trench transistor with insulative spacers.

U.S. Pat. No. 6,204,133 (Yu et al.) provides for the creation of a self-aligned junction for a reduced gate length.

U.S. Pat. No. 6,171,916 B1 (Suragawa et al.) provides for the creation of a semiconductor device having a buried gate electrode with silicided surfaces.

### SUMMARY OF THE INVENTION

A principle objective of the invention is to create a self-aligned gate electrode.

Another objective of the invention is to create a self-aligned gate electrode thereby separating the gate and source/drain regions in a self-aligned manner.

Yet another objective of the invention is to create a self-aligned gate electrode whereby the material for the gate electrode is extended to include metal.

Yet another objective of the invention is to create a self-aligned gate electrode using a simplified photolithographic process.

Yet another objective of the invention is to create a self-aligned gate electrode without a need for elevated source/drain regions.

Yet another objective of the invention is to create a self-aligned gate electrode without a need for epitaxy over the surface of the source/drain regions.

In accordance with the objectives of the invention a new method is provided for the creation of CMOS devices. A sacrificial layer is deposited over the surface of a silicon substrate. This sacrificial layer is instrumental in creating gate spacers and in doing so serves to separate the gate from the source/drain regions in a self-aligned manner.

### BRIEF DESCRIPTION OF THE DRAWINGS

FIGS. 1 through 4 show cross section of prior art methods of creating a gate electrode that resemble the processing sequence of the invention, as follows:

FIG. 1 shows a cross section of a substrate in the surface of which an active surface region has been defined, an opening has been created in the surface of the substrate, a layer of dielectric has been deposited for the formation of gate spacers.

FIG. 2 shows a cross section after the gate spacers have been formed.

FIG. 3 shows a cross section after the deposition of a layer of gate electrode material.

FIG. 4 shows a cross section after patterning of the gate electrode material and after salicidation of the contact surfaces of the gate electrode.

The invention is explained using FIGS. 5 through 11, as follows:

FIG. 5 is a cross section of the surface of a substrate, an active surface area has been defined, a sacrificial layer has been deposited over the surface of the substrate.

FIG. 6 is a cross section after patterning and etching of the sacrificial layer, an opening has been etched into the surface of the substrate, a layer of dielectric has been deposited for the creation of gate spacers.

FIG. 7 is a cross section after the gate spacers have been formed.

FIG. 8 is a cross section after the deposition of a layer of gate electrode material.

FIG. 9 is a cross section after the gate electrode material has been removed from above the trench that has been created for the gate electrode, the sacrificial layer has been removed from the surface of the substrate.

FIG. 10 shows a cross section after deposition of a layer of metal in preparation for the process of salicidation.

FIG. 11 shows a cross section after the process of salicidation has been completed.

### DESCRIPTION OF THE PREFERRED EMBODIMENTS

The invention addresses the above stated concerns and is based on:

1. Depositing a sacrificial layer over the surface of a silicon substrate; this sacrificial layer allows for the separation of the gate electrode and the source/drain regions of the gate electrode

2. Growth of selective silicon epitaxy is avoided for the formation of elevated source/drain surfaces

3. The gate electrode is formed using a self-aligned process; this makes the use of a very short channel length possible, and

4. The processes of the invention are compatible with conventional semiconductor processing and technology, no additional mask is required by the invention.

A prior art processing sequence that forms the basis for the process of the invention will next by described using FIGS. 1 through 4.

Shown in the cross section of FIG. 1 is the cross section of the surface of a substrate 100, two regions 102 of Shallow Trench Isolation (STI) have been formed in the surface of substrate 100 for electrically isolating the surface area of substrate 100 that is bounded by the STI regions 102. Opening 104 has been etched into the surface of substrate 100, in a location that aligns with the location over which a gate electrode is to be created. A layer 106 of dielectric, preferably comprising silicon dioxide, has been deposited over the surface of substrate 100, thereby including inside surfaces of opening 104 that has been created in the surface of substrate 100.

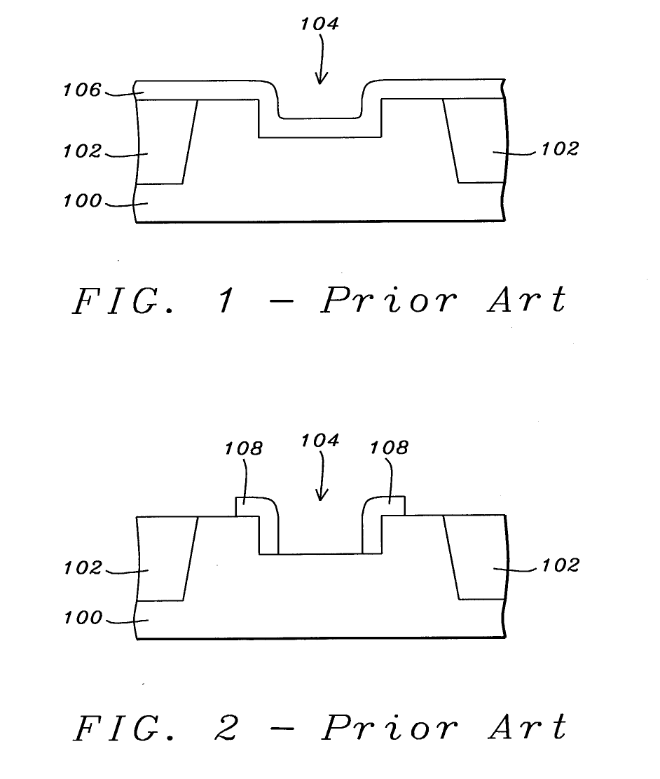

The cross section of FIG. 2 shows how the layer 106 of dielectric has been selectively etched (using a first photoresist mask), creating patterned and etched layers 108 of dielectric over sidewalls of opening 104 and from there extending by a distance over the surface of substrate 100. Conventional methods of photolithography and dielectric etching are applied for this purpose.

Next, FIG. 3, a layer 110 of gate dielectric is created over the bottom of openings 104, using conventional methods of surface oxidation. A layer 112 of gate electrode material, preferably comprising polysilicon, is then deposited over the surface of substrate 100, including the exposed surface of spacers 108 and the surface of the gate pad oxide 110.

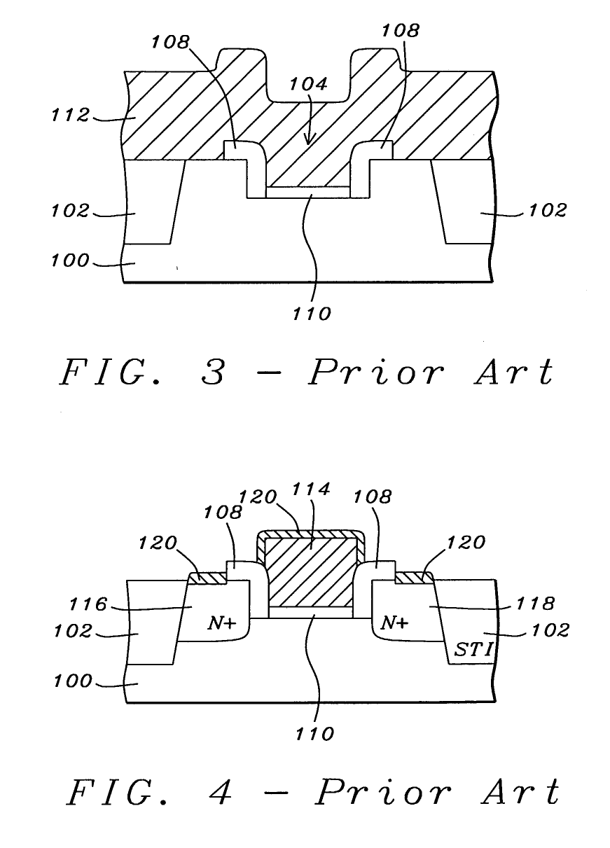

FIG. 4 shows the cross section of substrate 100 after the layer 112 of polysilicon has been patterned and etched (using a second photoresist mask), creating a layer 114 of gate material. Impurity implantations 116 and 118 are next performed, self aligned with the patterned and etched layer 114 of gate electrode material, to form the n+ source region 116 and the n+drain region 118 of impurity implantations in the surface of substrate 100.

As a final step, shown in cross section of FIG. 4, the contact surfaces of the gate electrode, that is the surface of the gate material 114 and the surface of the source/drain regions 116/118, as salicided applying conventional methods and materials of salicidation. Salicided surfaces 120 are in this manner created.

It is to be noted relative to the conventional process that has been described using FIGS. 1 through 4 that a complicated sequence of photolithography processing steps is required for first forming the gate spacers (FIG. 2) and then for the patterning and etching of the layer of gate electrode material (FIG. 4). Further, the selective etching of the deposited layer 106, FIG. 2, of dielectric requires a masking step. In addition, the separation between the salicided layer of gate material 120, FIG. 4, and the salicided surfaces 120 of the source/drain regions is determined by the created gate spacers 108 while the salicided contact surface 120 to the gate electrode is of a relatively large surface area.

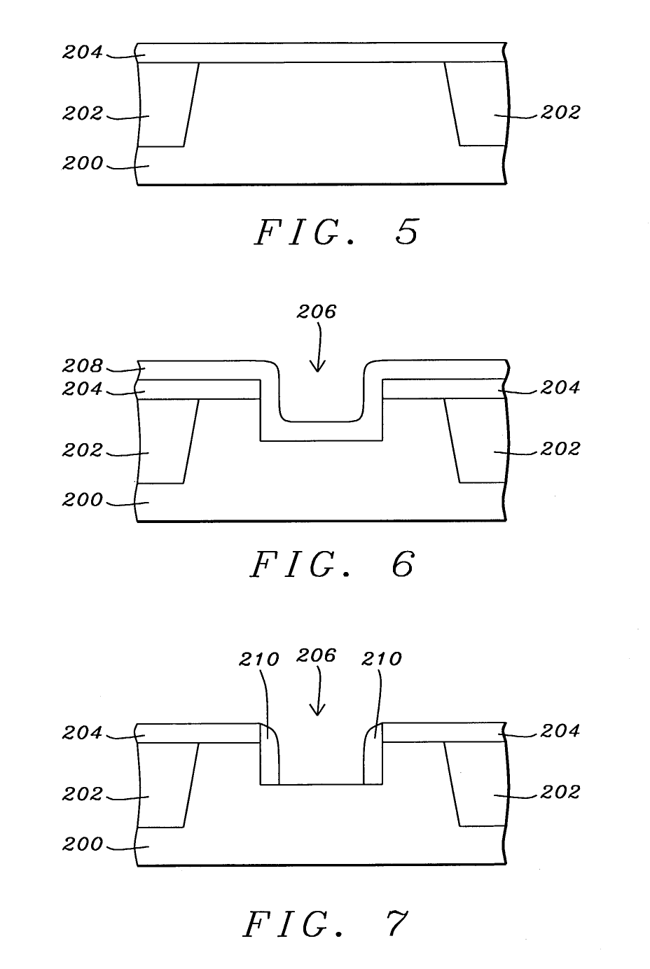

The invention will now be described in detail using FIGS. 5 through 11 for this purpose.

The invention starts, FIG. 5, with providing a semiconductor substrate 200 in the surface of which two regions 202 of STI have been formed. A layer 204, preferably comprising silicon nitride, has been deposited over the surface of substrate 200 to serve as a sacrificial layer.

The creation of STI regions 202 follows conventional methods. Care must be exercised in the creation of the STI regions since forming STI involves etching into silicon of the underlying substrate 200, which may result in the creation of dangling bonds and an irregular grain structure in the silicon substrate near the wells of the trench. During subsequent anneal processing (e.g. thermal oxidation for gate oxide formation), the irregular grain may provide migration avenues through which oxygen atoms can pass from the field oxide to the active area near the edges of field oxide. This aspect of the instant invention

STI regions 202 can be created using a variety of methods. For instance, one method is the use of Buried Oxide (BOX) isolation for shallow trenches. The method involves filling the trenches, which have been etched in the surface of substrate 200, with a Chemical Vapor Deposition (CVD) of silicon dioxide (SiO₂) which is then etched back or polished by chemical Mechanical Polishing (CMP) to yield a planar surface of regions 202. The shallow trenches etched for the BOX process are anisotropically plasma etched into the silicon. STI regions are typically formed around the active device to a depth between about 4,000 and 20,000 Angstroms.

Another approach in forming STI regions 202 is to deposit silicon nitride on thermally grown oxide. After deposition of the nitride, a shallow trench is etched into the substrate using a mask. A layer of oxide is then deposited into the trench so that the trench forms an area of insulate dielectric, which acts to isolate the devices in a chip and thus reduce the cross talk between active adjacent devices. The excess deposited oxide is polished and the trench planarized to prepare for the next level of the semiconductor device. The silicon nitride is provided to the silicon to prevent polishing of the masked silicon oxide of the device.

The layer 204 of silicon nitride (Si₃N₄) can be created using LPCVD or PECVD procedures, at a temperature between about 300 and 800 degrees C., preferably to a thickness between about 200 and 5,000 Angstroms.

The layer 204 of Si₃N₄ is patterned and etched, creating an opening 206, FIG. 6, through this layer 204 that extends into the surface of substrate 200 and that aligns with the surface area of substrate 200 over which a gate electrode is to be formed.

Layer 204 of silicon nitride can be etched applying standard photolithographic procedures via anisotropic RIE of the silicon nitride layer 204, using CHF₃, C₂F₆, C₄F₈, an inert gas or SF₆—O₂ as an etchant.

It must thereby be understood and emphasized, which is of critical importance to the invention, that layer 204 allows for the formation of layers of metal silicide in a self-aligned manner. In the absence of layer 204, an extra mask would be required to define the silicide region for the gate and the source/drain regions of the gate structure. Layer 204 is therefore of critical importance to the creation of self-aligned devices, the importance of layer 204 to the invention can therefore not be over-emphasized. The presence of layer 204 allows the formation of spacers 210, FIG. 7, these spacers 210 provide a separation between the body of the gate structure and the source/drain regions of the gate electrode. This will become more clear from the further description of the invention which follows.

A layer 208 of dielectric, preferably comprising silicon dioxide, is deposited over the surface of substrate 200, thereby including inside surfaces of opening 206.

Layer 208, preferably of silicon dioxide layer can be deposited by methods of PECVD. Other deposition means may alternatively be used to deposit this layer. However, PECVD is preferred because of the low deposition temperature. PECVD silicon dioxide may be deposited at temperatures between 200 and 350 degrees C. for SiH₄/O₂, SiCl₂H₄/O₂, SiCl₂H₂/N₂O or SiH₄/N₂O precursors. The silicon oxide layer is preferably deposited to a thickness of about 3,000 Angstroms.

The layer 208 of dielectric is next etched, creating, FIG. 7, spacers 210 over sidewalls of opening 206. Layer 208 of silicon dioxide can be etched by RIE or anisotropic plasma etching by using an etchant containing fluorocarbons, for example CF₄ or CHF₃.

Optionally, a lightly doped region can be formed at this time if desired.

The previously highlighted benefit and importance aspect of the invention, that is the advantage provided by layer 204, is now apparent in the cross section of FIG. 7: the presence of layer 204 has allowed for the creation of spacers 210, which provide adequate and desired separation between the (body of) the gate and the surface of the source/drain regions of the gate electrode. This will be more clear in the cross section shown in FIG. 11 and as further explained following. The silicidation of the gate surface and the surface of the source/drain regions can therefore be self-aligned.

A layer 212 of gate dielectric, FIG. 8, preferably comprising silicon dioxide or a high dielectric constant dielectric material, is created over the bottom surface of opening 206. A blanket layer 212 of gate dielectric comprising silicon dioxide can be formed to a thickness of about 110 Angstroms through a thermal oxidation method at a temperature of about 920 degrees C. for a time period of about 480 minutes. A layer 214 of gate material, preferably comprising doped polysilicon, is next deposited as shown in the cross section of FIG. 8.

As examples of dielectric materials with high dielectric constant that can be used for the creation of layer 212, FIG. 8, can be cited SiN (7.4) and Al₂O₃ (8.5). Other materials that meet requirements of high dielectric constant are titanium oxide (TiO₂), zirconium oxide (ZrO₂), tantalum oxide (Ta₂O₅), barium titanium oxide (BaTiO₃) and strontium titanium oxide (SrTiO₃).

A layer 214 of gate material, such as polysilicon, can be deposited to form a gate electrode by low pressure CVD (LPCVD) to a thickness between about 500 and 5,000 Angstroms and doped with POCl₃ in a furnace or by ion implantation.

The preferred materials for the creation of layer 214 can comprise doped polysilicon and can further be extended to include metal.

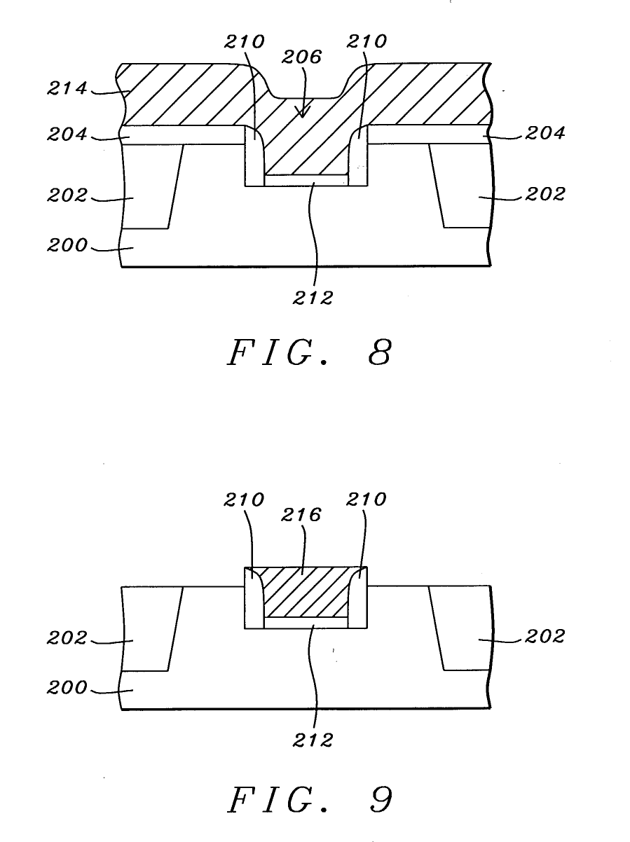

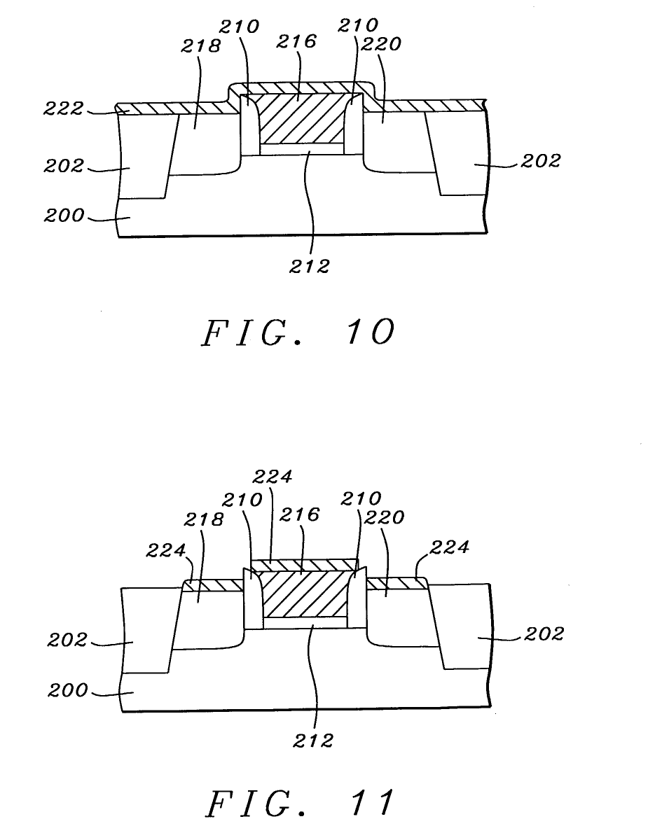

The deposited layer 214 of gate material is polished, significantly using methods of CMP, leaving the gate material in place inside opening 216, FIG. 9. The sacrificial layer 204 of silicon nitride is then removed from the surface of substrate 200. This leads to the cross section that is shown in FIG. 9. Layer 204 of silicon nitride can be removed by applying CHF₃, C₂F₆, C₄F₈, an inert gas or SF₆—O₂ as an etchant to the exposed surface of the layer 204 of silicon nitride. The removal of the sacrificial layer 204 exposes the surface of substrate 200, significantly facilitating following impurity implantation into the surface for the formation of source/drain regions.

Impurity implantations 218 (source) and 220 (drain), FIG. 10, are performed self-aligned with the patterned and etched layer 216 of gate material followed by the deposition of a layer 222 of salicide material.

As examples of the creation of source/drain regions 218/220 self-aligned with the gate structure 210/216 shown in cross section in FIG. 10 can be cited imparting a first conductivity dopant, used to create a lightly doped source and drain region, the first conductivity dopant being phosphorous, ion implanted at an energy between about 5 to 100 KeV, at a dose between about 1E11 to 1E14 atoms/cm².

Further can be cited a second conductivity imparting dopant, used to create a medium doped source and drain region, the second conductivity dopant being arsenic or phosphorous, ion implanted at an energy between about 5 to 50 KeV, at a dose between about 1E12 to 5E14 atoms/cm².

Further yet can be cited a third conductivity imparting dopant, used to create a heavily doped source and drain region, the third conductivity dopant being arsenic, ion implanted at an energy between about 5 to 150 KeV, at a dose between about 1E15 to 1E16 atoms/cm².

A layer 222, FIG. 10, of metal such as Co, Ti, Pt, W and the like is next deposited for purposes of salicidation of contact surfaces to the gate electrode. Salicidation of the deposited layer 22 of for instance titanium can be achieved by applying a first anneal by rapid thermal annealing in a temperature range between about 650 and 700 degrees C. for a time between about 20 and 40 seconds and then rapid second thermal annealed in a temperature range between about 800 and 900 degrees C. for a time between about 20 and 40 seconds. Unreacted titanium or any of the other potentially applicable metal is removed from the surface of the surface.

A preferred salicide process applies a pre-salicide clean using deluted HF (DHF) (diluted by about 100:1), followed by ion-amorphization and high temperature metal deposition of for instance a 300/250 Angstroms layer of Ti/TiN or a 110/250 Angstroms deposition of a layer of Co/TiN or a 200/250 Angstroms deposition of Ni/TiN or a 200/250 Angstroms deposition of Ni(metal)/TiN.

For the creation of TiSi₂ salicide, initial RTP is performed at 720 degrees C. for about 30 to 60 seconds followed by a final RTP at about 850 degrees C. for 10 to 30 seconds.

For the creation of CoSi₂ salicide, the RTP conditions are 550 degrees C. for 30 seconds followed by 750 degrees C. for about 10 to 30 seconds.

Salicide layers can be formed comprising titanium silicide (TiSi₂), nickel silicided (NiSi), nickel alloy silicide (Ni(metal)Si) and cobalt silicide (CoSi₂).

After the process of salicidation has been completed, the structure shown in cross section in FIG. 11 is obtained, wherein layer 224 is the salicided surface of the layer 216 of gate material and layers 224 are the salicided surface regions of the source/drain regions 218/220.

The invention can be summarized as follows:

Providing a substrate

Creating regions of field isolation oxide in the surface of the substrate

Depositing a sacrificial layer of for instance silicon dioxide over the surface of the substrate

Patterning and etching the sacrificial layer, thereby penetrating the surface of the substrate to form shallow trenches therein

Depositing a conformal layer of dielectric, such as silicon dioxide, over the surface of the substrate, including inside surface of the trench created in the surface of the substrate

Applying etchback to the deposited layer of dielectric, forming spacers over sidewalls of the shallow trench created in the surface of the substrate

Forming a layer of gate pad oxide over the exposed bottom surface of the shallow trench;

Depositing a layer of gate electrode material, such as polysilicon, amorphous silicon, metal

Removing the deposited gate electrode material from outside the trench using methods of CMP

Removing the sacrificial layer from the surface of the substrate, exposing the surface of the substrate

Performing source/drain impurity implantation self-aligned with the created layer of gate electrode material inside the shallow trench

Depositing a thin layer of metal, and

Applying heat-treatment to the deposited layer of metal, saliciding the layer of metal with underlying silicon.

As a separate embodiment of the invention, the steps of salicidation can be eliminated, that is the steps of:

Depositing a thin layer of metal, and

Applying heat-treatment to the deposited layer of metal, saliciding the layer of metal with underlying silicon.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method for the creation of a self-aligned gate electrode, comprising:
providing a substrate, an first active surface region having been defined in the substrate, a second surface area having been defined within the first active surface area for creation of a gate electrode aligned therewith;
creating a patterned and etched sacrificial layer over the substrate and surrounding the second surface area;
etching a shallow trench into the substrate bounded by the patterned and etched sacrificial layer; and
completing creation of a gate electrode self-aligned with the shallow trench by providing gate spacers, gate dielectric, gate material and gate impurity implantations, including salicidation of contact surfaces to the gate electrode.

2. The method of claim 1, the first active surface region being bounded by regions of Shallow Trench Isolation created in the substrate.

3. The method of claim 1, the sacrificial layer comprising silicon nitride.

4. The method of claim 1, the completing creation of a gate electrode comprising:
depositing a layer of dielectric over the patterned and etched sacrificial layer, including inside surfaces of the shallow trench;
etching the deposited layer of dielectric, removing the deposited layer of dielectric from the sacrificial layer and from a bottom surface of the shallow trench, creating gate spacers over sidewalls of the shallow trench;
creating a layer of gate dielectric over the bottom surface of the shallow trench;
depositing a layer of gate material over the patterned and etched sacrificial layer, filling a space between the gate spacers there-with;
removing the first layer of gate material from above the sacrificial layer, leaving a second layer of gate material in place in bounded by the gate spacers;
providing impurity implantations into the substrate self-aligned with the second layer of gate material, creating a gate electrode; and
saliciding contact surfaces of the gate electrode.

5. The method of claim 4, the layer of dielectric comprising silicon dioxide.

6. The method of claim 4, wherein the layer of gate material is doped polysilicon, undoped polysilicon, amorphous silicon, a metal or a metal compound.

7. The method of claim 4, wherein the layer of gate dielectric is SiO, SiN, Al₂O₃, titanium oxide (TiO₂), zirconium oxide (ZrO₂), tantalum oxide (Ta₂O₅), barium titanium oxide (BaTiO₃) or strontium titanium oxide (SrTiO₃).

8. The method of claim 4, the removing the first layer of gate material from above the sacrificial layer, leaving a second layer of gate material in place in bounded by the gate spacers comprising methods of Chemical Mechanical Polishing (CMP).

9. The method of claim 4, providing impurity implantations comprising providing source and drain impurity implantations.

10. The method of claim 4, saliciding contact surfaces of the gate electrode comprising:
depositing a layer of first metal over the gate electrode structure;
applying a thermal anneal to the layer of first metal; and
removing unreacted first metal from the gate electrode.

11. The method of claim 10, the first metal comprising a material selected from the group consisting of Co and Ti and Pt and W.

12. The method of claim 10, the applying a thermal anneal comprising a first anneal by rapid thermal annealing in a temperature range between about 650 and 700 degrees C. for a time between about 20 and 40 seconds and then rapid second thermal annealed in a temperature range between about 800 and 960 degrees C. for a time between about 20 and 40 seconds.

13. The method of claim 1, the sacrificial layer being deposited to a thickness between about 200 and 5,000 Angstroms.

14. A method for the creation of a self-aligned gate electrode, comprising:
providing a substrate, a first surface area having been defined over the substrate for the creation of a gate electrode aligned therewith;
creating regions of field isolation oxide in the substrate, the regions of field oxide bounding the first surface area of the substrate;
depositing a sacrificial layer over the substrate;
patterning and etching the sacrificial layer, creating an opening through the sacrificial layer aligned with the first surface are of the substrate, penetrating the substrate to form a shallow trench therein in alignment with the opening through the sacrificial layer;
depositing a conformal layer of dielectric over the patterned and etched sacrificial layer, including inside surfaces of the trench created in the substrate;
applying an etchback to the deposited layer of dielectric, forming spacers over sidewalls of the shallow trench created in the substrate, exposing the patterned and etched sacrificial layer, exposing a bottom surface of the shallow trench created in the substrate;
forming a layer of gate dielectric over the exposed bottom surface of the shallow trench;
depositing a layer of gate electrode material over the patterned and etched sacrificial layer, including exposed surfaces of the spacers created over sidewalls of the shallow trench;
removing the deposited gate electrode material from the patterned and etched sacrificial layer, exposing the patterned and etched sacrificial layer, creating a layer of gate electrode material bounded by the gate spacers;
removing the sacrificial layer from the substrate;
performing source/drain impurity implantations self-aligned with the created layer of gate electrode material bounded by the gate spacers;
depositing a thin layer of metal; and
applying heat-treatment to the deposited thin layer of metal, saliciding the thin layer of metal.

15. The method of claim 14, the creating regions of field isolation oxide comprising creating Shallow Trench Isolation regions.

16. The method of claim 14, the sacrificial layer comprising silicon nitride.

17. The method of claim 14, the conformal layer of dielectric comprising silicon dioxide.

18. The method of claim 14, the layer of gate material comprising material selected from the group consisting of doped polysilicon and undoped polysilicon and amorphous silicon and a metal.

19. The method of claim 14, the layer of gate dielectric comprising a material selected from the group consisting of SiN and Al₂O₃ and titanium oxide (TiO₂) and zirconium oxide (ZrO₂) and tantalum oxide (Ta₂O₅) and barium titanium oxide (BaTiO₃) and strontium titanium oxide (SrTiO₃).

20. The method of claim 14, the removing the deposited gate electrode material from the patterned and etched sacrificial layer comprising methods of Chemical Mechanical Polishing (CMP).

21. The method of claim 14, the thin layer of metal comprising a material selected from the group consisting of Co and Ti and Pt and W.

22. The method of claim 14, the applying heat-treatment to the deposited layer of metal comprising a first anneal by rapid thermal annealing in a temperature range between about 650 and 700 degrees C. for a time between about 20 and 40 seconds and then rapid second thermal annealed in a temperature range between about 800 and 900 degrees C. for a time between about 20 and 40 seconds.

23. The method of claim 14, the sacrificial layer being deposited to a thickness between about 200 and 5,000 Angstroms.

24. The method of claim 14, additionally removing unreacted thin layer of metal.

25. A method for the creation of a self-aligned gate electrode, comprising:
providing a substrate, an first active surface region having been defined in the substrate, a second surface area having been defined within the first active surface area for creation of a gate electrode aligned therewith;
creating a patterned and etched sacrificial layer over the substrate and surrounding the second surface area;
etching a shallow trench into the substrate bounded by the patterned and etched sacrificial layer; and
completing creation of a gate electrode self-aligned with the shallow trench by providing gate spacers, gate dielectric, gate material and gate impurity implantations.

26. The method of claim 25, the first active surface region being bounded by regions of Shallow Trench Isolation.

27. The method of claim 25, the sacrificial layer comprising silicon nitride.

28. The method of claim 25, the completing creation of a gate electrode comprising:
depositing a layer of dielectric over the patterned and etched sacrificial layer, including inside surface of the shallow trench;
etching the deposited layer of dielectric, removing the deposited layer of dielectric from the sacrificial layer and from a bottom surface of the shallow trench, creating gate spacers over sidewalls of the shallow trench;
creating a layer of gate dielectric over the bottom surface of the shallow trench;
depositing a layer of gate material over the patterned and etched sacrificial layer, filling a space between the gate spacers there-with;
removing the first layer of gate material from above the sacrificial layer, leaving a second layer of gate material in place in the space between the gate spacers; and
providing impurity implantations into the substrate self-aligned with the second layer of gate material, creating a gate electrode structure.

29. The method of claim 28, the layer of dielectric comprising silicon dioxide.

30. The method of claim 28, the layer of gate material comprising material selected from the group consisting of doped polysilicon and undoped polysilicon and amorphous silicon and a metal.

31. The method of claim 28, the layer of gate dielectric comprising a material selected from the group consisting of SiN and Al₂O₃ and titanium oxide (TiO₂) and zirconium oxide (ZrO₂) and tantalum oxide (Ta₂O₅) and barium titanium oxide (BaTiO₃) and strontium titanium oxide (SrTiO₃).

32. The method of claim 28, the removing the first layer of gate material from above the sacrificial layer, leaving a second layer of gate material in place in the space between the gate spacers comprising methods of Chemical Mechanical Polishing (CMP).

33. The method of claim 28, providing impurity implantations comprising providing source and drain impurity implantations.

34. The method of claim 28, the sacrificial layer being deposited to a thickness between about 200 and 5,000 Angstroms.

35. A method for the creation of a self-aligned gate electrode, comprising:
providing a substrate, a first surface area having been defined over the substrate for the creation of a gate electrode aligned therewith;
creating regions of field isolation oxide the substrate, the regions of field oxide bounding the first surface area of the substrate;
depositing a sacrificial layer over the substrate;
patterning and etching the sacrificial layer, creating an opening through the sacrificial layer aligned with the first surface are of the substrate, penetrating the substrate to form a shallow trench therein in alignment with the opening through the sacrificial layer;
depositing a conformal layer of dielectric over the patterned and etched sacrificial layer, including inside surfaces of the trench created in the substrate;
applying an etchback to the deposited layer of dielectric, forming spacers over sidewalls of the shallow trench created in the substrate, exposing the patterned and etched sacrificial layer, exposing a bottom surface of the shallow trench created in the substrate;
forming a layer of gate dielectric over the exposed bottom surface of the shallow trench;
depositing a layer of gate electrode material over the patterned and etched sacrificial layer, including exposed surfaces of the spacers created over sidewalls of the shallow trench;
removing the deposited gate electrode material from the patterned and etched sacrificial layer, exposing the patterned and etched sacrificial layer, creating a layer of gate electrode material bounded by the gate spacers;
removing the sacrificial layer from the substrate; and
performing source/drain impurity implantations self-aligned with the created layer of gate electrode material bounded by the gate spacers.

36. The method of claim 35, the creating regions of field isolation oxide comprising creating regions of Shallow Trench Isolation.

37. The method of claim 35, the sacrificial layer comprising silicon nitride.

38. The method of claim 35, the conformal layer of dielectric comprising silicon dioxide.

39. The method of claim 35, the layer of gate material comprising material selected from the group consisting of doped polysilicon and undoped polysilicon and amorphous silicon and a metal.

40. The method of claim 35, the layer of gate dielectric comprising a material selected from the group consisting of SiN and Al₂O₃ and titanium oxide (TiO₂) and zirconium oxide (ZrO₂) and tantalum oxide (Ta₂O₅) and barium titanium oxide (BaTiO₃) and strontium titanium oxide (SrTiO₃).

41. The method of claim 35, the removing the deposited gate electrode material from the patterned and etched sacrificial layer comprising methods of Chemical Mechanical Polishing (CMP).

42. The method of claim 35, the sacrificial layer being deposited to a thickness between about 200 and 5,000 Angstroms.

43. A method for the creation of a self-aligned gate electrode, comprising:
providing a substrate, a first surface area having been defined over the substrate for the creation of a gate electrode aligned therewith;
creating regions of field isolation oxide in the substrate, the regions of field oxide bounding the first surface area of the substrate;
depositing a sacrificial layer over the substrate;
patterning and etching the sacrificial layer, creating an opening through the sacrificial layer aligned with the first surface are of the substrate, penetrating the substrate to form a shallow trench therein in alignment with the opening through the sacrificial layer;
depositing a conformal layer of dielectric over the patterned and etched sacrificial layer, including inside surfaces of the trench created in the substrate;
applying an etchback to the deposited layer of dielectric, forming spacers over sidewalls of the shallow trench created in the substrate, exposing the patterned and etched sacrificial layer, exposing a bottom surface of the shallow trench created in the substrate;
forming a layer of gate dielectric over the exposed bottom surface of the shallow trench;
depositing a layer of gate electrode material over the patterned and etched sacrificial layer, including exposed surfaces of the spacers created over sidewalls of the shallow trench;
removing the deposited gate electrode material from the patterned and etched sacrificial layer using methods of Chemical Mechanical Polishing (CMP), exposing the patterned and etched sacrificial layer, creating a layer of gate electrode material bounded by the gate spacers;
removing the sacrificial layer from the substrate;
performing source/drain impurity implantations self-aligned with the created layer of gate electrode material bounded by the gate spacers;
depositing a thin layer of metal; and
applying heat-treatment to the deposited thin layer of metal, saliciding the thin layer of metal.

44. The method of claim 43, the creating regions of field isolation oxide comprising creating Shallow Trench Isolation regions.

45. The method of claim 43, the sacrificial layer comprising silicon nitride.

46. The method of claim 43, the conformal layer of dielectric comprising silicon dioxide.

47. The method of claim 43, the layer of gate material comprising material selected from the group consisting of doped polysilicon and undoped polysilicon and amorphous silicon and a metal.

48. The method of claim 43, the layer of gate dielectric comprising a material selected from the group consisting of SiN and Al₂O₃ and titanium oxide (TiO₂) and zirconium oxide (ZrO₂) and tantalum oxide (Ta₂O₅) and barium titanium oxide (BaTiO₃) and strontium titanium oxide (SrTiO₃).

49. The method of claim 43, the thin layer of metal comprising a material selected from the group consisting of Co and Ti and Pt and W.

50. The method of claim 43, the applying heat-treatment to the deposited layer of metal comprising a first anneal by rapid thermal annealing in a temperature range between about 650 and 700 degrees C. for a time between about 20 and 40 seconds and then rapid second thermal annealed in a temperature range between about 800 and 900 degrees C. for a time between about 20 and 40 seconds.

51. The method of claim 43, the sacrificial layer being deposited to a thickness between about 200 and 5,000 Angstroms.

52. The method of claim 43, additionally removing unreacted thin layer of metal.

53. A method for the creation of a self-aligned gate electrode, comprising:
providing a substrate, a first surface area having been defined over the substrate for the creation of a gate electrode aligned therewith;
creating regions of field isolation oxide in the substrate, the regions of field oxide bounding the first surface area of the substrate;
depositing a sacrificial layer over the substrate;
patterning and etching the sacrificial layer, creating an opening through the sacrificial layer aligned with the first surface are of the substrate, penetrating the substrate to form a shallow trench therein in alignment with the opening through the sacrificial layer;
depositing a conformal layer of dielectric over the patterned and etched sacrificial layer, including inside surfaces of the trench created in the substrate;
applying an etchback to the deposited layer of dielectric, forming spacers over sidewalls of the shallow trench created in the substrate, exposing the patterned and etched sacrificial layer, exposing a bottom surface of the shallow trench created in the substrate;
forming a layer of gate dielectric over the exposed bottom surface of the shallow trench;
depositing a layer of gate electrode material over the patterned and etched sacrificial layer, including exposed surfaces of the spacers created over sidewalls of the shallow trench;
removing the deposited gate electrode material from the patterned and etched sacrificial layer by methods of Chemical Mechanical Polishing (CMP), exposing the patterned and etched sacrificial layer, creating a layer of gate electrode material bounded by the gate spacers;
removing the sacrificial layer from the substrate; and
performing source/drain impurity implantations self-aligned with the created layer of gate electrode material bounded by the gate spacers.

54. The method of claim 53, the creating regions of field isolation oxide comprising creating regions of Shallow Trench Isolation.

55. The method of claim 53, the sacrificial layer comprising silicon nitride.

56. The method of claim 53, the conformal layer of dielectric comprising silicon dioxide.

57. The method of claim 53, the layer of gate material comprising material selected from the group consisting of doped polysilicon and undoped polysilicon and amorphous silicon and a metal.

58. The method of claim 54, the layer of gate dielectric comprising a material selected from the group consisting of SiN and Al₂O₃ and titanium oxide (TiO₂) and zirconium oxide (ZrO₂) and tantalum oxide (Ta₂O₅) and barium titanium oxide (BaTiO₃) and strontium titanium oxide (SrTiO₃).

59. The method of claim 54, the sacrificial layer being deposited to a thickness between about 200 and 5,000 Angstroms.

60. The method of claim 4, the gate dielectric comprising a dielectric having a dielectric constant of less than about 3.6.

61. The method of claim 14, the gate dielectric comprising a dielectric having a dielectric constant of less than about 3.6.

62. The method of claim 28, the gate dielectric comprising a dielectric having a dielectric constant of less than about 3.6.

63. The method of claim 35, the gate dielectric comprising a dielectric having a dielectric constant of less than about 3.6.

64. The method of claim 43, the gate dielectric comprising a dielectric having a dielectric constant of less than about 3.6.

65. The method of claim 53, the gate dielectric comprising a dielectric having a dielectric constant of less than about 3.6.
